(19) United States
(12) Patent Application Publication
(10) Pub. No.: US 2026/0311756 A1
(43) Pub. Date: Oct. 8, 2026

(54) Method and Apparatus for Computing Operations on a Non-volatile Memory Device

(71) Applicant: SINGAPORE UNIVERSITY OF TECHNOLOGY AND DESIGN, SINGAPORE (SG)

(72) Inventors: Shao-Xiang GO, SINGAPORE (SG); Kian-Guan LIM, SINGAPORE (SG); Desmond LOKE, SINGAPORE (SG)

(21) Appl. No.: 19/481,557

(22) PCT Filed: May 3, 2024
(86) PCT No.: PCT/SG2024/050289

§ 371 Date: Nov. 5, 2025

(30) Foreign Application Priority Data
May 5, 2023 (SG) 10202301264Q

(51) Int. Cl. G11C 13/00; H03F 3/45

(52) U.S. Cl. CPC G11C 13/0004; G11C 13/004; H03F 3/45; H03F 2203/45151

(57) ABSTRACT

A method and an apparatus for performing computing operations on a non-volatile memory device comprising, the method comprising: measuring an initial voltage of the non-volatile memory device, Vᵢₙᵢₜᵢₐₗ, before the non-volatile memory device responds to an input and a final voltage of the non-volatile memory device, V_{final}, after the non-volatile memory device responds to the input; calculating difference between V_{final} and Vᵢₙᵢₜᵢₐₗ; and comparing the difference between V_{final} and Vᵢₙᵢₜᵢₐₗ with a value to determine an output.

### FIELD

The present invention relates to semiconductor memory devices, in particular, a method and an apparatus for computing operations on a non-volatile memory device. Non-volatile memories and hybrid read and/or compute methods for non-volatile memory cells may be involved.

### BACKGROUND

With regard to semiconductor memory devices, they are generally categorised into two groups depending on whether the device retains stored data when disconnected from power. These two groups are non-volatile memories, which retain stored data when disconnected from power, and volatile memory cells, which lose data when not connected to power. Dynamic random access memory (DRAM) and static random access memory (SRAM) are examples of volatile memory devices. Examples of non-volatile memories include the flash memory, magnetic random access memory (MRAM), ferroelectric random access memory (FRAM), phase-change random access memory (PRAM), resistive random access memory (RRAM), read only memory (ROM), programmable read only memory (PROM), electrically programmable read only memory (EPROM) and electrically erasable and programmable read only memory (EEPROM).

Due to its excellent down-scalability, fast switching speed and high cycle endurance, PRAM is a leading candidate for next generation non-volatile memory devices. Researchers are pursuing ways to enhance PRAM device performance. For instance, researchers are seeking approaches to improve the speed of write operations, number of logic operations, as well as storage capacity. When the absolute impedance is utilized, traditional experiments have shown that small changes in the impedance can be sufficient to achieve a small number of logic operations.

### SUMMARY

According to an example of the present disclosure, there are provided a method and an apparatus as claimed in the independent claims. Some optional features are defined in the dependent claims.

### BRIEF DESCRIPTION OF THE DRAWINGS

Examples in the present disclosure will be better understood and readily apparent to one skilled in the art from the following written description, by way of example only and in conjunction with the drawings, in which:

FIG. 1 is a block/circuit diagram of a memory system according to an example of the present disclosure.

FIG. 2 is a simulated timing diagram of the operations of the memory system in FIG. 1 according to an example of the present disclosure.

FIG. 3 is a block/circuit diagram of the memory system comprising a different type of comparator according to an example of the present disclosure.

FIG. 4 is a simulated timing diagram of the operations of the memory system in FIG. 3 according to an example of the present disclosure.

FIG. 5 is a block diagram of a computing platform comprising the memory system according to an example of the disclosure.

### DETAILED DESCRIPTION

Generally, most memory operations harness the same primary structure for data storage and register operations. This is in contrast to von Neumann architectures containing separate storage and processing units. Thus, memory operations can decrease the energy cost of computing in data centers substantially.

Developing suitable material systems for non-volatile memory is very difficult. Various studies focused on examining novel device architectures. The present disclosure examines the use or application of existing non-volatile memories. Examples discussed in the present disclosure are based on phase-change random access memory (PRAM), also called Phase-change memory (PCM). However, the same concepts can also be implemented with other types of memory devices, including FRAM, RRAM, MRAM, flash memory, ROM, PROM, EPROM, EEPROM and other memories, and are not limited to PRAM.

In particular, phase-change memory (also known as PCM, PCME, PRAM, PCRAM, OUM (ovonic unified memory) and C-RAM or CRAM (chalcogenide RAM)) is a type of non-volatile random-access memory that exploits the unique behaviour of chalcogenide glass. In PRAM, heat produced by the passage of an electric current through a heating element generally made of titanium nitride is used to either quickly heat and quench the glass, making it amorphous, or to hold it in its crystallization temperature range for some time, thereby switching it to a crystalline state. PRAM has the ability to achieve a number of distinct intermediary states, thereby having the ability to hold multiple bits in a single cell. The material states of PRAM can be carefully controlled to allow it to be transformed into one of four distinct material states: the previous amorphous or crystalline states, along with two new partially crystalline ones. Each of these states has different electrical properties that can be measured during reads, allowing a single cell to represent two bits, doubling memory density.

In an example of the present disclosure, all four (M) material states of a PRAM comprising nanostructured chalcogenide material are harnessed for data storage and register operations. A hybrid M state-based configuration framework for developing in-memory operation is proposed. Single cell, non-volatile, and reprogrammable shift register operations are featured as well. A multiple-level-per-volt different-initial-state multilevel set process with further computing in the M state-based platform was attained. Such process is unique.

Examples discussed in the present disclosure showcase the simplest cases of a programmable shift register model with a serial-in-serial-out processing approach. More complicated reprogrammable processing schemes using the proposed M state-based framework or platform may be used and as a result, non-volatile shift register modes with multiple processing strategies can be achieved. Novel switching device types based on nanostructured chalcogenide materials can be involved. This opens a route for designing next generation low-energy electronic systems using nanostructure-based chalcogenide materials.

The method and/or apparatus of examples of the present disclosure can be applied in smartphones, digital cameras, data centers, global positioning systems (GPS), gaming devices, laptops, electronic musical instruments, and other applications.

According to one example of the present disclosure, there is provided an apparatus or a memory system comprising a non-volatile memory device; a differential amplifier that calculates difference between a final voltage of (or across) the non-volatile memory device (V_{final}) after the non-volatile memory responds to an input and an initial voltage of (or across) the non-volatile memory device (Vᵢₙᵢₜᵢₐₗ) before the non-volatile memory responds to the input; an absolute amplifier that computes the absolute difference between V_{final} and Vᵢₙᵢₜᵢₐₗ; a voltage divider that computes a percentage of Vᵢₙᵢₜᵢₐₗ, for example, half of the Vᵢₙᵢₜᵢₐₗ (½ Vᵢₙᵢₜᵢₐₗ); and a comparator that compares the absolute difference between the V_{final} and Vᵢₙᵢₜᵢₐₗ with the percentage of Vᵢₙᵢₜᵢₐₗ. The apparatus or memory system is configured for performing computing operations on the non-volatile memory device. Computing operations may include inputting, processing, outputting, storing and controlling. In particular, computing operations may involve reading from memory, writing to memory and/or performing logic operations.

Examples of the present disclosure are capable of harnessing a percentage change in the impedance of for example, a phase-change random access memory (PRAM), such that the change relative to the original impedance can induce an impedance window that is large. In these examples, the non-volatile memory device can be a PRAM cell. Such change relative to the original impedance is high enough to result in an increased impedance window, which leads to a large number of logic operations (as opposed to a small number of logic operations). The logic operation can be performed by comparing the percent change in impedance with a value, for example, 0.5, or compare the absolute difference between a final voltage drop across the PRAM cell (V_{final}) and an initial voltage drop across a PRAM cell (Vᵢₙᵢₜᵢₐₗ) with half of Vᵢₙᵢₜᵢₐₗ. For example, each of the four (M) material states of the PRAM cell can produce different voltage differences (V_{final}−Vᵢₙᵢₜᵢₐₗ) and different outputs after such voltage differences are comparison with a predetermined value, which may be a percentage of the voltage value of Vᵢₙᵢₜᵢₐₗ and may be lesser than the voltage value of Vᵢₙᵢₜᵢₐₗ.

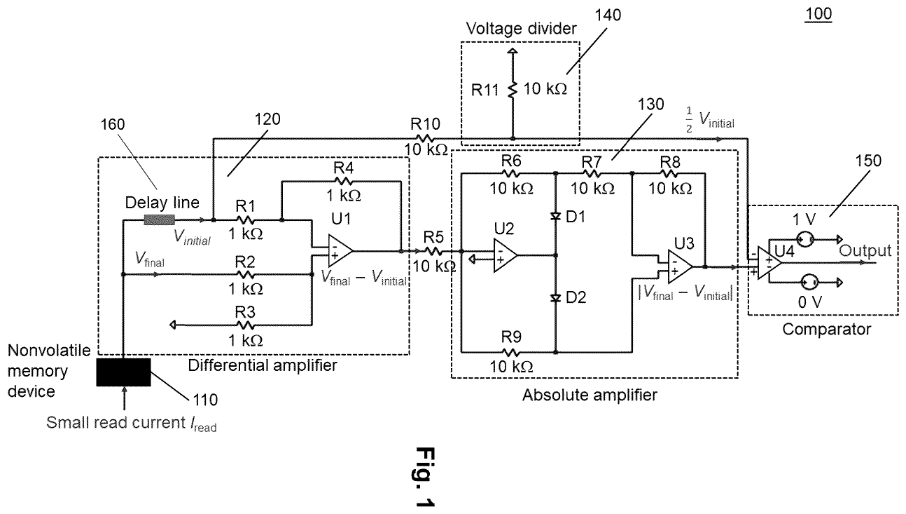

FIG. 1 is a block/circuit diagram of a memory system 100 according to an example of the present disclosure.

Referring to FIG. 1, there is provided a memory system 100 comprising a non-volatile memory device 110 (e.g. a PRAM cell), a differential amplifier 120, an absolute amplifier 130, a voltage divider 140 and a comparator 150.

The non-volatile memory device 110 outputs an initial voltage, Vᵢₙᵢₜᵢₐₗ, before any input is received by the non-volatile memory device 110. In response to an input, for instance, a small read current, I_{read}, the non-volatile memory device 110 outputs a final voltage, V_{final}. Both signals of initial voltage, Vᵢₙᵢₜᵢₐₗ, and final voltage, V_{final}, are then inputted to the differential amplifier 120. Specifically, Vᵢₙᵢₜᵢₐₗ is first measured and inputted to a delay line 160, which is provided to delay the input of Vᵢₙᵢₜᵢₐₗ (i.e. introduce a time delay to input Vᵢₙᵢₜᵢₐₗ) so that Vᵢₙᵢₜᵢₐₗ can be inputted to the differential amplifier 120 synchronously with V_{final}. V_{final} is measured after the non-volatile memory device 110 receives an input i.e. the read current, I_{read}. The construction of the delay line 160 may include hardware like inductors and capacitors, and/or it may be implemented digitally with the help of a processor.

The differential amplifier 120 has a circuit comprising an operational amplifier (op amp) U1 with an inverting input (negative) connected to a first end of a resistor R1 and a second end of the resistor R1 is connected to an output of the non-volatile memory device 110. A non-inverting input (positive) of the op amp U1 is connected to a first end of a resistor R2 and a second end of the resistor R2 is connected to the output of the non-volatile memory device 110. The output of the op amp U1 is connected to a first end of a feedback resistor R4 and a second end of the resistor R4 is connected to the inverting input of the op amp U1 and to the resistor R1. The resistor R4 is the feedback resistor of the op amp U1. The non-inverting input of the op amp U1 is also connected to a first end of a Resistor R3 and a second end of the resistor R3 is connected to ground.

The delay line 160 is connected to resistor R1 and to a first end of a resistor R10. A second end of the resistor R10 is connected to a voltage divider 140 comprising a resistor R11 with a first end connected to the resistor R10. A second end of the resistor R11 is connected to ground.

The output of the op amp U1 is connected to a first end of a resistor R5. A second end of the resistor R5 is connected to an inverting input (negative) of an op amp U2 and a first end of a resistor R6 and a first end of a resistor R9. A non-inverting input (positive) of the op amp U2 is connected to ground. A second end of the resistor R6 is connected to a first end of a resistor R7 and an anode of a diode D1. A second end of the resistor R9 is connected to a non-inverting input (positive) of an op amp U3 and a cathode of a diode D2. A cathode of the diode D1 is connected to an anode of the diode D2. The anode of the diode D2 is connected to a non-inverting input (positive) of the op amp U3. An output of the op amp U2 is connected to the anode of the diode D1 and the cathode of the diode D2. A second end of the resistor R7 is connected to a first end of a feedback resistor R8 and an inverting input (negative) of the op amp U3. The resistor R8 is the feedback resistor of op amp U3 and a second end of the resistor R8 is connected to an output of the op amp U3.

The first end of the resistor R11 is connected to an inverting input (negative) of an op amp U4. The output of the op amp U3 is connected to a non-inverting input (positive) of the op amp U4. The op amp U4 performs the function of the comparator 150.

In the present example, the resistance value of each of the resistors R1 to R4 is 1 k-ohm (k(Ω) and the resistance values of each of the resistors R5 to R11 is 10 k-ohm (kΩ).

During operation, the differential amplifier 120 computes the difference between the inputted V_{final} and Vᵢₙᵢₜᵢₐₗ. In particular, the differential amplifier 120 amplifies the difference between the inputted signals V_{final} and Vᵢₙᵢₜᵢₐₗ. Superposition is used to calculate the output voltage resulting from each input voltage, and then the two output voltages are added to arrive at the final output voltage. The signal of the difference between the V_{final} and Vᵢₙᵢₜᵢₐₗ is supplied to the absolute amplifier 130.

The absolute amplifier 130 (also known as “absolute-value circuit”) outputs a positive Voltage value to be used for comparison by the comparator 150. In particular, the signal of the absolute difference between the V_{final} and Vᵢₙᵢₜᵢₐₗ is provided to the comparator 150 upon the computation of the absolute difference between the V_{final} and Vᵢₙᵢₜᵢₐₗ by the absolute amplifier 130.

The delay line 160 inputs Vᵢₙᵢₜᵢₐₗ to the voltage divider 140. The voltage divider 140 divides Vᵢₙᵢₜᵢₐₗ into half and provides a signal of half of Vᵢₙᵢₜᵢₐₗ (½ Vᵢₙᵢₜᵢₐₗ) to the comparator 150.

Finally, the comparator 150 compares the signal of the absolute difference between the V_{final} and Vᵢₙᵢₜᵢₐₗ with the signal of ½ Vᵢₙᵢₜᵢₐₗ. The comparator outputs a ‘1’ if the absolute difference between the V_{final} and Vᵢₙᵢₜᵢₐₗ is larger than ½ Vᵢₙᵢₜᵢₐₗ, whereas for the case in which the difference between the V_{final} and Vᵢₙᵢₜᵢₐₗ is smaller than ½ Vᵢₙᵢₜᵢₐₗ, a ‘0’ results. The output of the comparator 150 may be the output of a logic or computing operation.

In the example of FIG. 1, a small read current, I_{read} is used. It should be appreciated that instead of a small read current, I_{read}, the input to the non-volatile memory device 110 can also be a write current or a read and write current depending on the application.

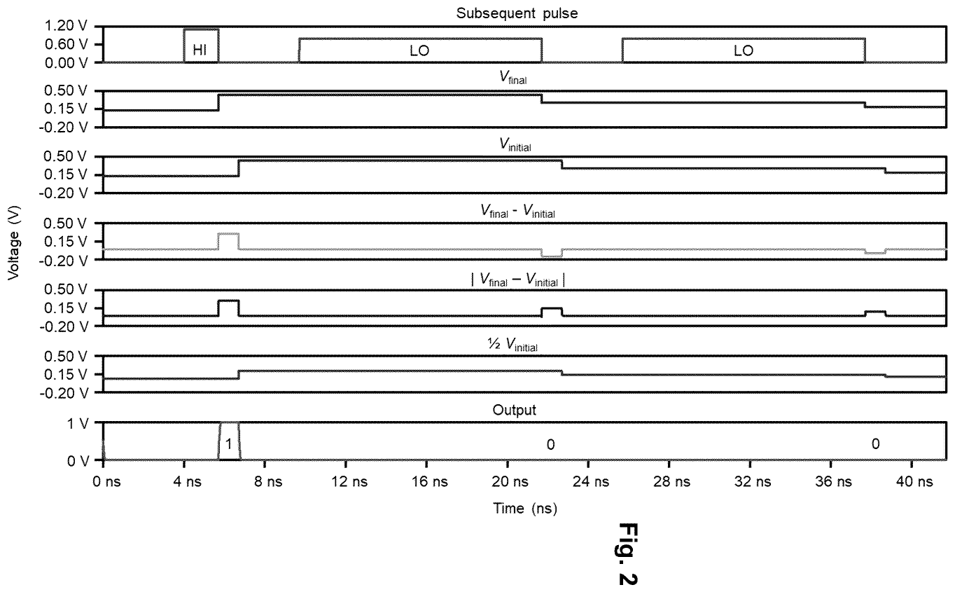

FIG. 2 is a simulated timing diagram of the operations of the memory system 100 of FIG. 1. FIG. 2 shows voltage (square) pulses across a time period of about 40 nanoseconds (ns) of an input signal (fluctuating between high HI or low LO) inputted to the non-volatile memory device 110. FIG. 2 also shows voltage (square) pulses across a time period of about 40 ns of signals for V_{final}, Vᵢₙᵢₜᵢₐₗ, V_{final}−Vᵢₙᵢₜᵢₐₗ, absolute value of V_{final}−Vᵢₙᵢₜᵢₐₗ (|V_{final}−Vᵢₙᵢₜᵢₐₗ|), and half of Vᵢₙᵢₜᵢₐₗ (½ Vᵢₙᵢₜᵢₐₗ). FIG. 2 further shows voltage (square) pulses across a time period of about 40 ns of a binary output signal (fluctuating between 1 or 0) of the comparator 150.

In particular, at time of about 6 ns, a signal HI passes through the non-volatile memory device 110 and the signal of V_{final} become high. The signal of Vᵢₙᵢₜᵢₐₗ remains low and the signal of the difference between the V_{final} and Vᵢₙᵢₜᵢₐₗ is positive. At this time, the signal of the absolute difference between the V_{final} and Vᵢₙᵢₜᵢₐₗ stays positive and is stronger than the signal of ½ Vᵢₙᵢₜᵢₐₗ. Consequently, the output ‘1’ results.

Next, at time of about 22 ns, the signal LO passes through the non-volatile memory device 110 and the signal of V_{final} becomes low. At this time, the signal of Vᵢₙᵢₜᵢₐₗ remains high, and the signal of the difference between V_{final} and Vᵢₙᵢₜᵢₐₗ is negative. The signal of the absolute difference between the V_{final} and Vᵢₙᵢₜᵢₐₗ becomes positive but is weaker than the signal of 1/2 Vᵢₙᵢₜᵢₐₗ. Accordingly, this leads to the output ‘0’.

Finally, at time of about 38 ns, the output ‘0’ is induced with the same type of signals utilized at about the time of 22 ns.

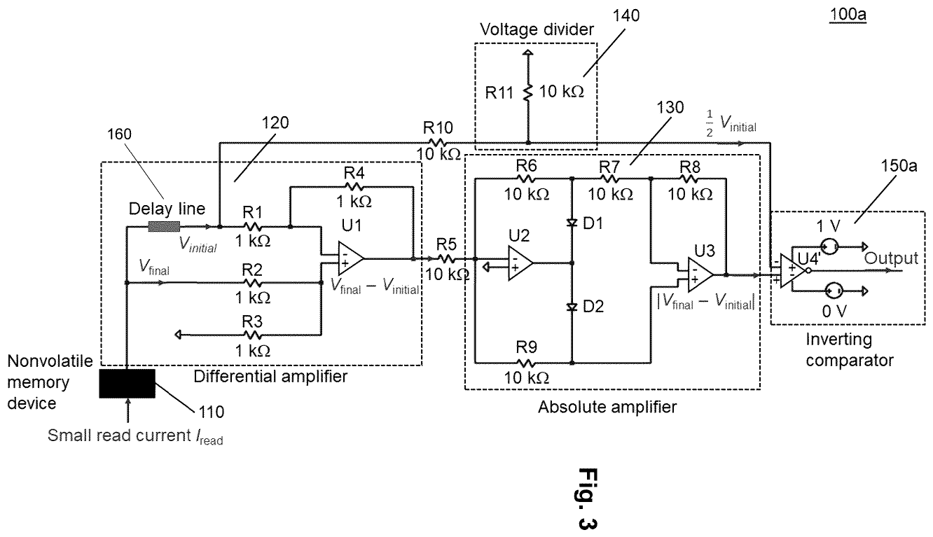

FIG. 3 is a block/circuit diagram of the memory system 100a comprising a different type of comparator according to an example of the present disclosure. Elements of FIG. 3 that are similar to the elements of FIG. 1 are given the same reference numerals and the functions of similar elements are the same. The memory system 100a is the same as the memory system 100 of FIG. 1 except that the comparator 150a of FIG. 3 is an inverting comparator instead of the non-inverting comparator 150 of FIG. 1. Specifically, the op amp U4′ of FIG. 3 is an inverting op amp instead of the non-inverting op amp U4 of FIG. 1. Hence, the output of the op amp U4′ of FIG. 3 is the inverse of that of the op amp U4 of FIG. 1.

Referring to FIG. 3, the memory system 100a comprises the non-volatile memory device 110 (e.g. PRAM cell), delay line 160, differential amplifier 120, absolute amplifier 130, voltage divider 140 and inverting comparator 150a. The circuits of the non-volatile memory device 110, delay line 160, differential amplifier 120, absolute amplifier 130, and voltage divider 140 in FIG. 3 are the same as the non-volatile memory device 110, differential amplifier 120, absolute amplifier 130, and voltage divider 140 in FIG. 1. All the resistors R1 to R11 in FIG. 3 are the same as the resistors R1 to R11 in FIG. 1. Op amps U1 to U3 in FIG. 3 are the same as Op amps U1 to U3 in FIG. 1. The first end of the resistor R11 is connected to an inverting input (negative) of the op amp U4′ of FIG. 3. The output of the op amp U3 of FIG. 3 is connected to a non-inverting input (positive) of the op amp U4′ of FIG. 3. The op amp U4′ of FIG. 3 performs the function of the inverting comparator 150a.

The inverting comparator 150a compares the signal of the absolute difference between the V_{final} and Vᵢₙᵢₜᵢₐₗ With the signal of ½ Vᵢₙᵢₜᵢₐₗ. If the absolute difference between the V_{final} and Vᵢₙᵢₜᵢₐₗ is smaller than ½ Vᵢₙᵢₜᵢₐₗ, the inverting comparator outputs a ‘1’, whereas a ‘0’ results for the case in which the absolute difference between the V_{final} and Vᵢₙᵢₜᵢₐₗ is larger than ½ Vᵢₙᵢₜᵢₐₗ. These outputs of the inverting comparator 150a are opposite of that of the comparator 150 of FIG. 1. The output of the comparator 150a may be the output of a logic or computing operation.

In the example of FIG. 3, a small read current, I_{read} is used. It should be appreciated that instead of a small read current, I_{read}, the input to the non-volatile memory device 110 can also be a write current or a read and write current depending on the application.

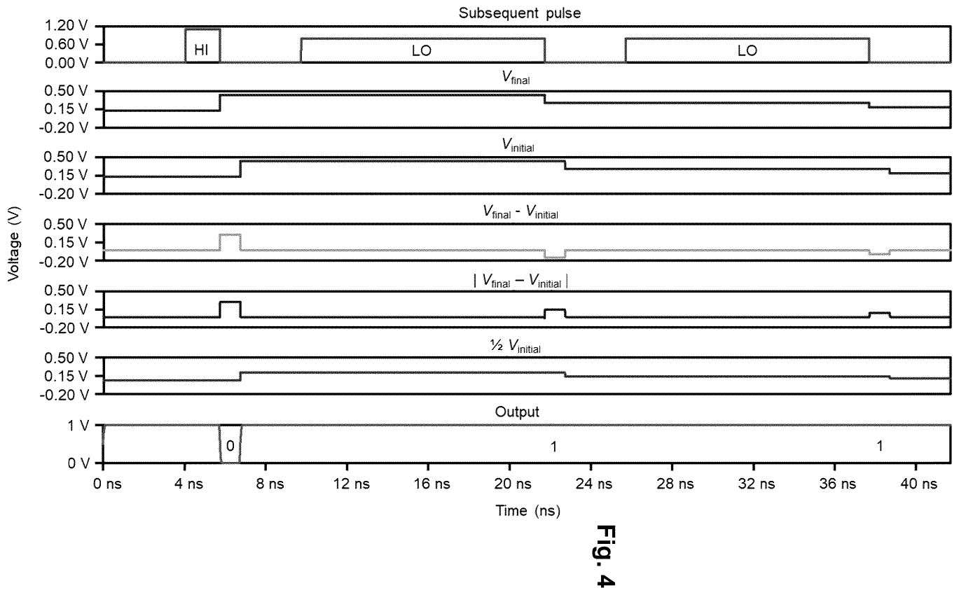

FIG. 4 is the simulated timing diagram of the operations of the memory system 100a of FIG. 3. FIG. 4 shows voltage (square) pulses across a time period of about 40 nanoseconds (ns) of an input signal (fluctuating between high HI or low LO) inputted to the non-volatile memory device 110 of FIG. 3. FIG. 2 also shows voltage (square) pulses across a time period of about 40 ns of signals for V_{final}, Vᵢₙᵢₜᵢₐₗ, V_{final}−Vᵢₙᵢₜᵢₐₗ, absolute value of V_{final}−Vᵢₙᵢₜᵢₐₗ (|V_{final}−Vᵢₙᵢₜᵢₐₗ|), and half of Vᵢₙᵢₜᵢₐₗ (½ Vᵢₙᵢₜᵢₐₗ). FIG. 4 further shows voltage (square) pulses across a time period of about 40 ns of a binary output signal (fluctuating between 1 or 0) of the inverting comparator 150a.

Referring to FIG. 4, the signal HI passes through the non-volatile memory device 110 and the signal of V_{final} becomes high at time of about 6 ns. The signal of Vᵢₙᵢₜᵢₐₗ stays low and the signal of the difference between the V_{final} and Vᵢₙᵢₜᵢₐₗ is positive. The signal of the absolute difference between the V_{final} and Vᵢₙᵢₜᵢₐₗ remains positive and is stronger than the signal of ½ Vᵢₙᵢₜᵢₐₗ. As a result, the output ‘0’occurs.

Next, the signal LO passes through the non-volatile memory device 110 and the signal of V_{final} becomes low at time of about 22 ns. The signal of Vᵢₙᵢₜᵢₐₗ remains high, and the signal of the difference between the V_{final} and Vᵢₙᵢₜᵢₐₗ is negative. The signal of the absolutes difference between the V_{final} and Vᵢₙᵢₜᵢₐₗ becomes positive but is weaker than the signal of ½ Vᵢₙᵢₜᵢₐₗ. This results in the output ‘1’ accordingly.

Finally, the output ‘1’ emanates with the same type of signals harnessed at time of about 22 ns.

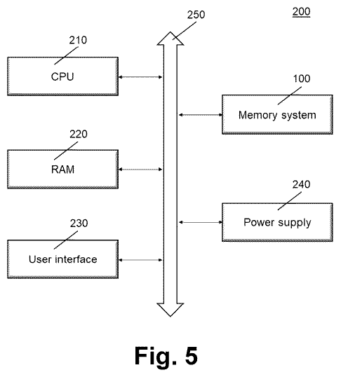

FIG. 5 is a block diagram of an apparatus, computer, machine, computing system or computing platform 200 comprising the memory system 100 of FIG. 1 according to an example of the present disclosure. In another example, the memory system 100 of the apparatus 200 can be replaced by the memory system 100a of FIG. 3.

Referring to FIG. 5, there is present a central processing unit (CPU) 210, RAM 220, user interface 230, power supply 240 and the memory system 100 of FIG. 1 are included in apparatus 200.

Through a system bus 250, the memory system 100 is connected to the CPU 210, RAM 220, user interface 230 and power supply 240. The memory system 100 stores data provided via the user interface 230 or processed by CPU 210.

The memory system 100 of FIGS. 1 and 100a of FIG. 3 can be utilized in various types of devices, such as an electronic device capable of transmitting and receiving information in a wireless environment, electronic device comprising a computer network, and electronic device comprised of a telematics network or radio frequency identification (RDIF). The electronic device may include a computing system, computer, portable computer, ultra-mobile PC (UMPC), workstation, net-book, personal digital assistant (PDA), web tablet, wireless phone, mobile phone, smart phone, e-book, portable multimedia player (PMP), digital camera, digital audio recorder/player, digital picture/video recorder/player, portable game machine, navigation system, black box and/or television.

The memory system 100 of FIGS. 1 and 100a of FIG. 3 can be packaged using various types of packages or package configurations such as a metric quad flat pack (MQFP), small outline integrated circuit (SOIC), shrink small outline package (SSOP), thin small outline package (TSOP), thin quad flat pack (TQFP), system in package (SIP), multi-chip package (MCP), wafer-level fabricated package (WFP), wafer-level processed stack package (WSP), package on package (POP), ball grid array (BGA), chain scale package (CSP), plastic leaded chip carrier (PLCC), plastic dual in-line package (PDIP), die in waffle pack, die in wafer form, chip on board (COB) and ceramic dual in-line package (CERDIP).

Examples of the present disclosure may comprise the following features.

A method for performing computing operations on a non-volatile memory device (e.g. 110 of FIG. 1 and FIG. 3), the method comprising:
measuring an initial voltage of the non-volatile memory device, Vᵢₙᵢₜᵢₐₗ, before the non-volatile memory device responds to an input and a final voltage of the non-volatile memory device, V_{final}, after the non-volatile memory device responds to the input;
calculating difference between V_{final} and Vᵢₙᵢₜᵢₐₗ; and
comparing the difference between V_{final} and Vᵢₙᵢₜᵢₐₗ with a value to determine an output.

With regard to the method, the value may be a percentage of Vᵢₙᵢₜᵢₐₗ and is lesser than Vᵢₙᵢₜᵢₐₗ.

The method may comprise:
computing absolute difference between V_{final} and Vᵢₙᵢₜᵢₐₗ;
calculating and outputting half of Vᵢₙᵢₜᵢₐₗ (½ Vᵢₙᵢₜᵢₐₗ) as the value; and
comparing the absolute difference between V_{final} and Vᵢₙᵢₜᵢₐₗ with the value to determine the output.

With regard to the method, the output may be binary.

With regard to the method, the non-volatile memory device may be a phase-change random access memory (PRAM).

With regard to the method, the non-volatile memory device may comprise a nanostructured chalcogenide material for providing a plurality of material states.

The method may comprise:
after measuring Vᵢₙᵢₜᵢₐₗ, delaying the calculation of the difference between V_{final} and Vᵢₙᵢₜᵢₐₗ until V_{final} is measured.

An apparatus for performing computing operations on a non-volatile memory device (e.g. 110 of FIG. 1 and FIG. 3), wherein the apparatus comprises:
a differential amplifier (e.g. 120 of FIG. 1 and FIG. 3) configured for measuring an initial voltage of the non-volatile memory device, Vᵢₙᵢₜᵢₐₗ, before the non-volatile memory device responds to an input and a final voltage of the non-volatile memory device, V_{final}, after the non-volatile memory device responds to the input and calculating difference between V_{final} and Vᵢₙᵢₜᵢₐₗ; and
a comparator (e.g. 150 of FIGS. 1, 150a of FIG. 3) for comparing the difference between V_{final} and Vᵢₙᵢₜᵢₐₗ with a value to determine an output.

With regard to the apparatus, the value may be a percentage of Vᵢₙᵢₜᵢₐₗ and is lesser than Vᵢₙᵢₜᵢₐₗ.

The apparatus may comprise:
an absolute amplifier (e.g. 130 of FIG. 1 and FIG. 3) for computing absolute difference between V_{final} and Vᵢₙᵢₜᵢₐₗ; and
a voltage divider (e.g. 140 of FIG. 1 and FIG. 3) for calculating and outputting half of Vᵢₙᵢₜᵢₐₗ (½ Vᵢₙᵢₜᵢₐₗ) as the value,
wherein the comparator is configured to compare the absolute difference between V_{final} and Vᵢₙᵢₜᵢₐₗ with the value to determine the output.

With regard to the apparatus, the output may be binary.

With regard to the apparatus, the non-volatile memory device may be a phase-change random access memory (PRAM).

With regard to the apparatus, the non-volatile memory device may comprise a nanostructured chalcogenide material for providing a plurality of material states.

With regard to the apparatus, the comparator may be an inverting comparator (e.g. 150a of FIG. 3).

The differential amplifier may comprise a delay line (e.g. 160 in FIG. 1 and FIG. 3) to introduce a time delay to input the measured Vᵢₙᵢₜᵢₐₗ for the calculation of the difference between V_{final} and Vᵢₙᵢₜᵢₐₗ until V_{final} is measured.

In the specification and claims, unless the context clearly indicates otherwise, the term “comprising” has the non-exclusive meaning of the word, in the sense of “including at least” rather than the exclusive meaning in the sense of “consisting only of”. The same applies with corresponding grammatical changes to other forms of the word such as “comprise”, “comprises” and so on.

While the invention has been described in the present disclosure in connection with a number of embodiments and implementations, the invention is not so limited but covers various obvious modifications and equivalent arrangements, which fall within the purview of the appended claims. Although features of the invention are expressed in certain combinations among the claims, it is contemplated that these features can be arranged in any combination and order.

1. A method for performing computing operations on a non-volatile memory device, the method comprising:
measuring an initial voltage of the non-volatile memory device, Vᵢₙᵢₜᵢₐₗ, before the non-volatile memory device responds to an input and a final voltage of the non-volatile memory device, V_{final}, after the non-volatile memory device responds to the input;
calculating difference between V_{final} and Vᵢₙᵢₜᵢₐₗ; and
comparing the difference between V_{final} and Vᵢₙᵢₜᵢₐₗ with a value to determine an output.

2. The method of claim 1, wherein the value is a percentage of Vᵢₙᵢₜᵢₐₗ and is lesser than Vᵢₙᵢₜᵢₐₗ.

3. The method of claim 2, the method comprising:
computing absolute difference between V_{final} and Vᵢₙᵢₜᵢₐₗ;
calculating and outputting half of Vᵢₙᵢₜᵢₐₗ (½ Vᵢₙᵢₜᵢₐₗ) as the value; and
comparing the absolute difference between V_{final} and Vᵢₙᵢₜᵢₐₗ with the value to determine the output.

4. The method of claim 1, wherein the output is binary.

5. The method of claim 1, wherein the non-volatile memory device is a phase-change random access memory (PRAM).

6. The method of any one of claim 5, wherein the non-volatile memory device comprises a nanostructured chalcogenide material for providing a plurality of material states.

7. The method of claim 1, the method comprising:
after measuring Vᵢₙᵢₜᵢₐₗ, delaying the calculation of the difference between V_{final} and Vᵢₙᵢₜᵢₐₗ until V_{final} is measured.

8. An apparatus for performing computing operations on a non-volatile memory device, wherein the apparatus comprises:
a differential amplifier configured for measuring an initial voltage of the non-volatile memory device, Vᵢₙᵢₜᵢₐₗ, before the non-volatile memory device responds to an input and a final voltage of the non-volatile memory device, V_{final}, after the non-volatile memory device responds to the input and calculating difference between V_{final} and Vᵢₙᵢₜᵢₐₗ; and
a comparator for comparing the difference between V_{final} and Vᵢₙᵢₜᵢₐₗ with a value to determine an output.

9. The apparatus of claim 8, wherein the value is a percentage of Vᵢₙᵢₜᵢₐₗ and is lesser than Vᵢₙᵢₜᵢₐₗ.

10. The apparatus of claim 9, wherein the apparatus comprises:
an absolute amplifier for computing absolute difference between V_{final} and Vᵢₙᵢₜᵢₐₗ; and
a voltage divider for calculating and outputting half of Vᵢₙᵢₜᵢₐₗ (½ Vᵢₙᵢₜᵢₐₗ) as the value,
wherein the comparator is configured to compare the absolute difference between V_{final} and Vᵢₙᵢₜᵢₐₗ with the value to determine the output.

11. The apparatus of claim 8, wherein the output is binary.

12. The apparatus of claim 8, wherein the non-volatile memory device is a phase-change random access memory (PRAM).

13. The apparatus of claim 12, wherein the non-volatile memory device comprises a nanostructured chalcogenide material for providing a plurality of material states.

14. The apparatus of claim 8, wherein the comparator is an inverting comparator.

15. The apparatus of claims 8, wherein the differential amplifier comprises a delay line to introduce a time delay to input the measured Vᵢₙᵢₜᵢₐₗ for the calculation of the difference between V_{final} and Vᵢₙᵢₜᵢₐₗ until V_{final} is measured.
